(19) United States
(12) Patent Application Publication
(10) Pub. No.: US 2026/0323999 A1
(43) Pub. Date: Oct. 15, 2026

(54) Display Device, Method Of Manufacturing The Same, And Electronic Device Including The Same

(71) Applicant: Samsung Display Co., Ltd., Yongin-si (KR)

(72) Inventors: HANBIT KIM, Yongin-si (KR); JEONG WON KIM, Yongin-sikr (KR); THANH TIEN NGUYEN, Yongin-si (KR); SANGGUN CHOI, Yongin-si (KR); SEONGBAIK CHU, Yongin-si (KR); Taehyun Hong, Yongin-si (KR)

(73) Assignee: Samsung Display Co., Ltd., Yongin-si (KR)

(21) Appl. No.: 19/695,595

(22) Filed: Jun. 2, 2026

(30) Foreign Application Priority Data
Apr. 9, 2025 (KR) 10-2025-0125505

(51) Int. Cl. H10D 30/67; H10D 30/01

(52) U.S. Cl. CPC H10D 30/6736; H10D 30/0312; H10D 30/6723

(57) ABSTRACT

A display device is provided. The display device includes a substrate, an active pattern disposed on the substrate, a first gate insulating layer disposed on the active pattern, a second gate insulating layer disposed on the substrate, a gate electrode disposed on the second gate insulating layer, and a light-emitting element disposed on the gate electrode. The active pattern includes a first conductor area, a second conductor area, and a channel area disposed between the first conductor area and the second conductor area. The first gate insulating layer overlaps with the second conductor area and a portion of the channel area. The first gate insulating layer is spaced apart from the first conductor area. The second gate insulating layer covers the active pattern and the first gate insulating layer. The gate electrode overlaps the channel area.

### CROSS-REFERENCE TO RELATED APPLICATION

This application claims priority to and the benefit of Korean Patent Application No. 10-2025-0125505, filed on Sep. 4, 2025, the disclosure of which is incorporated by reference herein in its entirety.

### TECHNICAL FIELD

The present disclosure relates to a display device for displaying images, a method of manufacturing the display device, and an electronic device that includes the display device.

### BACKGROUND

With the development of information technology, the importance of a display device, which is a connection medium between a user and information, has been highlighted. For example, the use of display devices such as liquid crystal display (LCD) device, organic light emitting diode (OLED) display device, plasma display panel (PDP) device, quantum dot display device or the like is increasing.

A display device may include a display part and a driving part, and the driving part may generate a driving signal and provide the driving signal to the display part. In order for the driving part to generate the driving signal, the driving part may include a transistor, and a silicon semiconductor (e.g., amorphous silicon, polycrystalline silicon, etc.) and/or an oxide semiconductor may be used as a semiconductor layer of the transistor.

### BRIEF SUMMARY

Aspects of the present disclosure provide a display device with improved device (or element) characteristics.

In some aspects, the present disclosure provides a method of manufacturing the display device.

In some aspects, the present disclosure provides an electronic device that includes the display device.

However, aspects of the present disclosure are not restricted to those set forth herein. The above and other aspects of the present disclosure will become apparent to one of ordinary skill in the art to which the present disclosure pertains by referencing the detailed description of the present disclosure given below.

According to some aspects, a display device is provided that includes: a substrate, a first gate insulating layer disposed on the active pattern, a second gate insulating layer disposed on the substrate, a gate electrode disposed on the second gate insulating layer, and a light-emitting element disposed on the gate electrode. The active pattern includes a first conductor area, a second conductor area, and a channel area disposed between the first conductor area and the second conductor area. The first gate insulating layer overlaps the second conductor area and a portion of the channel area when viewed in the thickness direction of the display device. The first gate insulating layer is spaced apart from the first conductor area when viewed in the thickness direction of the display device. The second gate insulating layer covers the active pattern and the first gate insulating layer. The gate electrode overlaps the channel area.

In some aspects, the first gate insulating layer includes a first side surface and a second side surface. The first side surface and the second side surface are along a direction, the direction being parallel to a short side or a long side of the display device. The first side surface overlaps the channel area of the active pattern, the second side surface is a surface opposite to the first side surface, and the second side surface overlaps the second conductor area of the active pattern.

In some aspects, the first side surface of the first gate insulating layer overlaps a central portion of the channel area.

In some aspects, a side surface of the active pattern overlapping the second conductor area protrudes further in the direction away from a central portion of the active pattern compared to the second side surface of the first gate insulating layer.

In some aspects, a side surface of the active pattern overlapping the second conductor area and the second side surface of the first gate insulating layer are aligned parallel to each other when viewed in the thickness direction of the display device.

In some aspects, the gate electrode overlaps the first side surface of the first gate insulating layer when viewed in the thickness direction of the display device. The gate electrode is spaced apart from the second side surface of the first gate insulating layer when viewed in the thickness direction of the display device.

In some aspects, the second gate insulating layer extends along a profile of an upper surface of the active pattern and a profile of an upper surface of the first gate insulating layer. The gate electrode extends along a profile of an upper surface of the second gate insulating layer.

In some aspects, a sum of a thickness of the first gate insulating layer and a thickness of the second gate insulating layer disposed between the second conductor area and the gate electrode is greater than a thickness of the second gate insulating layer disposed between the first conductor area and the gate electrode.

In some aspects, the second gate insulating layer has a flat upper surface such that a top surface of the second gate insulating layer has a same distance from the substrate in the thickness direction, and the gate electrode has a substantially flat upper surface such that a top surface of the gate electrode has a same distance from the substrate in the thickness direction.

In some aspects, the display device further includes a source electrode and a drain electrode disposed between the gate electrode and the light-emitting element. The source electrode is connected to the first conductor area through a first contact hole penetrating the second gate insulating layer. The drain electrode is connected to the second conductor area through a second contact hole penetrating the first gate insulating layer and the second gate insulating layer.

In some aspects, a method of manufacturing a display device is proved that includes: forming a preliminary semiconductor layer on a substrate; forming a preliminary insulating layer on the preliminary semiconductor layer; forming a photoresist layer on the preliminary insulating layer; forming a photoresist pattern by exposing and developing the photoresist layer; simultaneously etching the preliminary semiconductor layer and the preliminary insulating layer using the photoresist pattern as a mask to form an active pattern and a first gate insulating layer on the active pattern, the first gate insulating layer overlapping a portion of the active pattern; forming a second gate insulating layer covering the active pattern and the first gate insulating layer on the substrate; forming a gate electrode on the second gate insulating layer; and forming a light-emitting element on the gate electrode. The second gate insulating layer overlaps the active pattern when viewed in the thickness direction of the display device.

In some aspects, the photoresist pattern includes a first portion and a second portion connected to the first portion. The first portion has a first thickness and the second portion has a second thickness. The first thickness is less than the second thickness. The forming of the active pattern and the first gate insulating layer using the photoresist pattern as the mask includes removing a portion of the preliminary semiconductor layer spaced apart from the photoresist pattern when viewed in the thickness direction of the display device, and removing a first portion of the preliminary insulating layer spaced apart from t the photoresist pattern when viewed in the thickness direction of the display device and removing a second portion of the preliminary insulating layer that overlaps the first portion of the photoresist pattern when viewed in the thickness direction of the display device.

In some aspects, the forming the photoresist pattern includes exposing the photoresist layer using a photomask. The photomask includes a light-blocking pattern blocking light, a first light-transmitting portion having a first light transmittance, and a second light-transmitting portion having a second light transmittance. The first light transmittance is lower than the first light transmittance.

In some aspects, the method further includes doping a portion of the active pattern after forming the gate electrode. The active pattern includes a first conductor area, a second conductor area, and a channel area disposed between the first conductor area and the second conductor area.

In some aspects, the first gate insulating layer includes a first side surface and a second side surface. The first side surface and the second side surface are along a direction, the direction being parallel to a short side or a long side of the display device. The first side surface overlaps the channel area of the active pattern, the second side surface is a surface opposite to the first side surface, and the second side surface overlaps the second conductor area of the active pattern.

In some aspects, a side surface of the active pattern overlapping the second conductor area and the second side surface of the first gate insulating layer are aligned parallel to each other when viewed in the thickness direction of the display device.

In some aspects, the method further includes cleaning the active pattern after forming the active pattern and the first gate insulating layer. The cleaning of the active pattern includes removing a portion of the second side surface of the first gate insulating layer. The side surface of the active pattern overlapping the second conductor area protrudes further in a first direction away from a central portion of the active pattern compared to the second side surface of the first gate insulating layer.

In some aspects, the second gate insulating layer is formed along a profile of an upper surface of the active pattern and a profile of an upper surface of the first gate insulating layer, and the gate electrode is formed along a profile of an upper surface of the second gate insulating layer.

In some aspects, the method further includes polishing an upper surface of the second gate insulating layer after forming the second gate insulating layer. The second gate insulating layer has a substantially flat upper surface such that a top surface of the second gate insulating layer has a same distance from the substrate in the thickness direction, and the gate electrode has a substantially flat upper surface such that a top surface of the gate electrode has a same distance from the substrate in the thickness direction.

In some aspects, an electronic device is provided that includes a processor configured to transmit an image data signal and an input control signal, and a display device configured to receive the image data signal and the input control signal from the processor. The display device includes: a substrate, an active pattern disposed on the substrate, a first gate insulating layer disposed on the active pattern, a second gate insulating layer disposed on the substrate, a gate electrode disposed on the second gate insulating layer, and a light-emitting element disposed on the gate electrode. The active pattern includes a first conductor area, a second conductor area, and a channel area disposed between the first conductor area and the second conductor area. The first gate insulating layer overlaps the second conductor area and a portion of the channel area, and the first gate insulating layer is spaced apart from the first conductor area. The second gate insulating covers the active pattern and the first gate insulating layer. The gate electrode overlaps the channel area.

In some aspects, a display device is provides that includes an active pattern, a first gate insulating layer, a second gate insulating layer, and a gate electrode. The active pattern includes a first conductor area, a second conductor area, and a channel area. The first gate insulating layer is disposed on the active pattern, overlapping the second conductor area and a portion of the channel area. The first gate insulating layer is spaced apart from the first conductor area. The second gate insulating layer covers the active pattern and the first gate insulating layer. The gate electrode is disposed on the second gate insulating layer, and the gate electrode overlaps the channel area.

In some aspects, a thickness of a gate insulating layer between the second conductor area and the gate electrode may be greater than a thickness of a gate insulating layer between the first conductor area and the gate electrode. Accordingly, the concentration of the electric field in the second conductor area can be reduced, the hot carrier phenomenon can be reduced, and the device (or element) reliability of a thin film transistor can be improved.

In some aspects, a method of manufacturing a display device is provided that includes forming the active pattern and the first gate insulating layer by simultaneously etching a preliminary semiconductor layer and a preliminary insulating layer using a photoresist pattern as a mask. By simultaneously etching the preliminary semiconductor layer and the preliminary insulating layer after forming the preliminary insulating layer and a photoresist layer on the preliminary semiconductor layer, in the process of forming the active pattern, the preliminary semiconductor layer can be prevented from directly being in contact with the photoresist layer or the photoresist pattern. Accordingly, a problem in which an interface (or an upper surface) of the preliminary semiconductor layer is contaminated by the photoresist layer or the photoresist pattern can be prevented, and the device (or element) characteristics of the thin film transistor can be improved.

### BRIEF DESCRIPTION OF THE DRAWINGS

The above and other aspects and features of the present disclosure will become more apparent by describing in detail embodiments thereof with reference to the accompanying drawings, in which:

FIG. 1 is a block diagram illustrating a display device according to an embodiment of the present disclosure;

FIG. 2A is a plan view illustrating an example of the display device of FIG. 1;

FIG. 2B is a plan view illustrating another example of the display device of FIG. 1;

FIG. 3 is a cross-sectional view taken along the line I-I′ of FIG. 2A;

FIG. 4 is an enlarged cross-sectional view of the area A of FIG. 3;

FIG. 5 is a plan view illustrating a display device according to an embodiment of the present disclosure;

FIG. 6 is a cross-sectional view taken along the line II-II′ of FIG. 5;

FIG. 7 is an enlarged cross-sectional view of the area B of FIG. 6;

FIGS. 8, 9, 10, 11, 12, 13, 14, 15, 16, 17, 18, and 19 are cross-sectional views illustrating a method of manufacturing a display device according to an embodiment of the present disclosure;

FIG. 20 is a block diagram illustrating an electronic device according to an embodiment of the present disclosure; and

FIG. 21 is a schematic view of an electronic device according to various embodiments of the present disclosure.

### DETAILED DESCRIPTION

While specific embodiments are shown in the drawings and described in detail herein below, the present disclosure may be modified in a variety of ways and realized in many different forms. Accordingly, it will be appreciated that the present disclosure is not limited to the specific disclosed forms, and should be construed to include all modifications, equivalents, or replacements included within the spirit and scope of the present disclosure.

In the drawings, sizes and relative sizes of components, layers and regions may be exaggerated or reduced for clarity. For example, a size and thickness of each component shown in the drawing are arbitrarily shown for convenience of explanation, and thus the present implementation of the teachings of the present disclosure are not necessarily limited to what is shown. When describing with reference to the accompanying drawings, identical or corresponding components in the drawings are given the same reference numerals, and redundant descriptions thereof are omitted.

It is to be understood that, although the terms “first”, “second”, “third”, etc. may be used herein to describe various elements, these elements should not be limited by these terms. These terms are used to distinguish one element from another element. For instance, a first element discussed below could be termed a second element without departing from the teachings of the present disclosure. Similarly, the second element could also be termed a first element.

As used herein, the term “and/or” includes any and all combinations of one or more of the associated listed items. For example, in the present disclosure, “A and/or B” refers to either A, B, or both A and B, and “at least one of A and B” indicates the case where it is A, or B, or both A and B.

As used herein, singular expressions, such as “a,” “an” and “the” are intended to include the plural expressions, unless the context clearly indicates otherwise.

Furthermore, relative terms, such as “lower” or “bottom” and “upper” or “top” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

It is also to be understood that when an element is referred to as being “on”, “connected to” or “coupled to” to another element, it can be directly disposed on/connected to/coupled to the other element or intervening element(s) may be present therebetween. In contrast, when an element is referred to as being “directly on”, “directly connected to” or “directly coupled to” to another element, there are no intervening elements present. Other words used to describe the relationship between elements should be interpreted in a like fashion (e.g., “between” versus “directly between,” “adjacent” versus “directly adjacent,” etc.).

Additionally, the terms “about,” “generally,” and “substantially” are intended to mean, and a person of ordinary skill would understand them to mean that slight deviations from absolute are included within the scope of the term so modified.

In the present disclosure, a plane may be defined along a first direction DR1 and a second direction DR2 transverse to the first direction DR1. For example, the first direction DR1 and the second direction DR2 may be perpendicular to each other. In addition, a third direction DR3 may be perpendicular to the plane. The third direction DR3 may refer to a thickness direction of each component.

Furthermore, it is to be understood that the coordinate system is not limited to the three axes DR1, DR2 and DR3 of the orthogonal coordinate system and may be interpreted in a broad sense that includes them. For example, the DR1, DR2, and DR3 may be orthogonal to each other, but they may also refer to different directions that are not orthogonal to each other. The plane can be defined by the first direction DR1 and the second direction DR2, where DR2 is transverse to DR1. It is further to be understood that the term “plan view” refers to the third direction DR3 which is normal to the plane. The term “cross-sectional view” can be defined by DR1 and DR3, or by DR2 and D3.

In addition, the terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

In some aspects, a display device may be included in various electronic devices. In some aspects, an electronic device according includes the display device described above, and may further include a module or device having additional functions in addition to the display device.

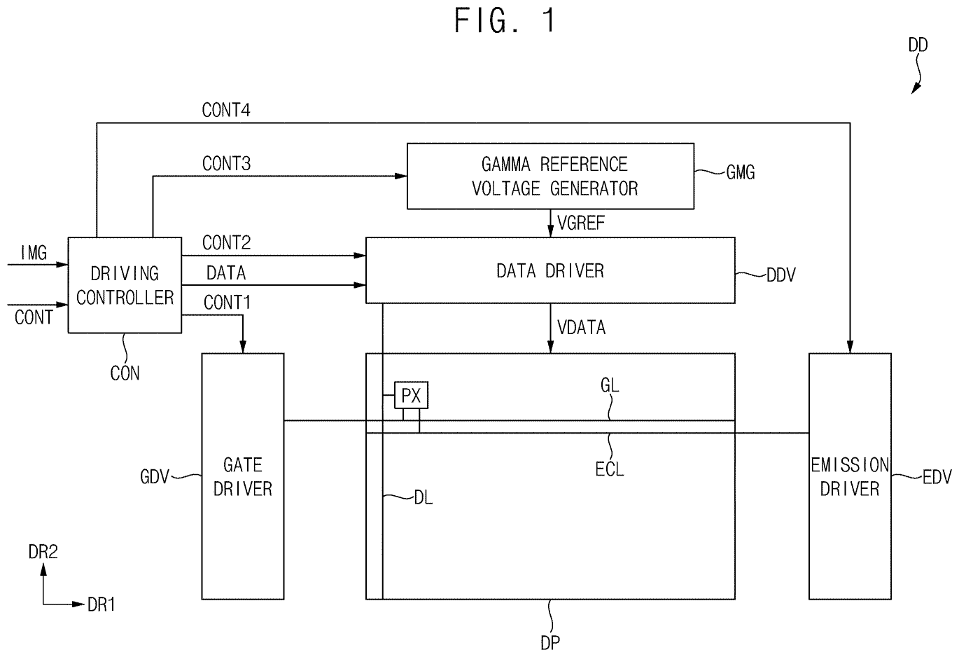

FIG. 1 is a block diagram illustrating a display device according to an embodiment of the present disclosure.

Referring to FIG. 1, a display device DD according to an embodiment of the present disclosure may include a display panel DP and a panel driver that drives the display panel DP. The panel driver may include a driving controller CON, a gate driver GDV, a gamma reference voltage generator GMG, a data driver DDV, and an emission driver EDV.

For example, the driving controller CON and the data driver DDV may be integrally formed as a single module. A driving module in which the driving controller CON and the data driver DDV are integrally formed may be referred to as a timing controller embedded data driver (TED).

The display panel DP may include gate lines GL, emission lines ECL, data lines DL, and pixels PX. The pixels PX may be electrically connected to the gate lines GL, the emission lines ECL, and the data lines DL. Each of the pixels PX may generate light in response to a driving signal. For example, each of the gate lines GL may extend in a first direction DR1, and each of the emission lines ECL may extend in the first direction DR1. Each of the data lines DL may extend in a second direction DR2 intersecting the first direction DR1. For example, the first direction DR1 and the second direction DR2 may be perpendicular to each other.

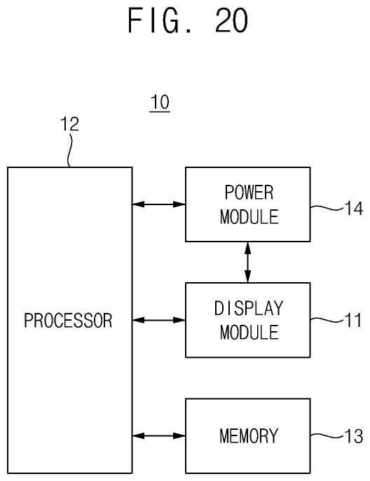

The driving controller CON may receive an image data signal IMG and an input control signal CONT from an external device (e.g., a processor 12 of FIG. 20). For example, the image data signal IMG may include red image data, green image data, and blue image data. In an embodiment, the image data signal IMG may further include white image data. The input control signal CONT may include a vertical synchronization signal, a horizontal synchronization signal, a data enable signal, a master clock signal, and the like.

The driving controller CON may generate a first control signal CONT1, a second control signal CONT2, a third control signal CONT3, a fourth control signal CONT4, and a data signal DATA based on the image data signal IMG and the input control signal CONT.

The driving controller CON may output the first control signal CONT1 to the gate driver GDV. The first control signal CONT1 may include a vertical start signal and a gate clock signal. The driving controller CON may output the second control signal CONT2 and the data signal DATA to the data driver DDV. The second control signal CONT2 may include a horizontal start signal and a load signal. The driving controller CON may output the third control signal CONT3 to the gamma reference voltage generator GMG. The driving controller CON may output the fourth control signal CONT4 to the emission driver EDV.

The gate driver GDV may generate gate signals in response to the first control signal CONT1. The gate driver GDV may output the gate signals to the gate lines GL.

The gamma reference voltage generator GMG may generate a gamma reference voltage VGREF in response to the third control signal CONT3. The gamma reference voltage generator GMG may provide the gamma reference voltage VGREF to the data driver DDV. For example, the gamma reference voltage generator GMG may be disposed in the driving controller CON or may be disposed in the data driver DDV.

The data driver DDV may receive the second control signal CONT2 and the data signal DATA from the driving controller CON, and may receive the gamma reference voltage VGREF from the gamma reference voltage generator GMG. The data driver DDV may convert the data signal DATA into a data voltage VDATA in an analog form by using the gamma reference voltage VGREF. The data driver DDV may output the data voltage VDATA to the data lines DL.

The emission driver EDV may generate emission signals in response to the fourth control signal CONT4. The emission driver EDV may output the emission signals to the emission lines ECL.

In FIG. 1, for convenience of description, the gate driver GDV is illustrated as being disposed on a first side of the display panel DP, and the emission driver EDV is illustrated as being disposed on a second side opposite to the first side of the display panel DP, but the present disclosure is not necessarily limited thereto. For example, both the gate driver GDV and the emission driver EDV may be disposed on the first side of the display panel DP. For another example, both the gate driver GDV and the emission driver EDV may be disposed on opposite sides of the display panel DP. For another example, the gate driver GDV and the emission driver EDV may be integrally formed as a single module.

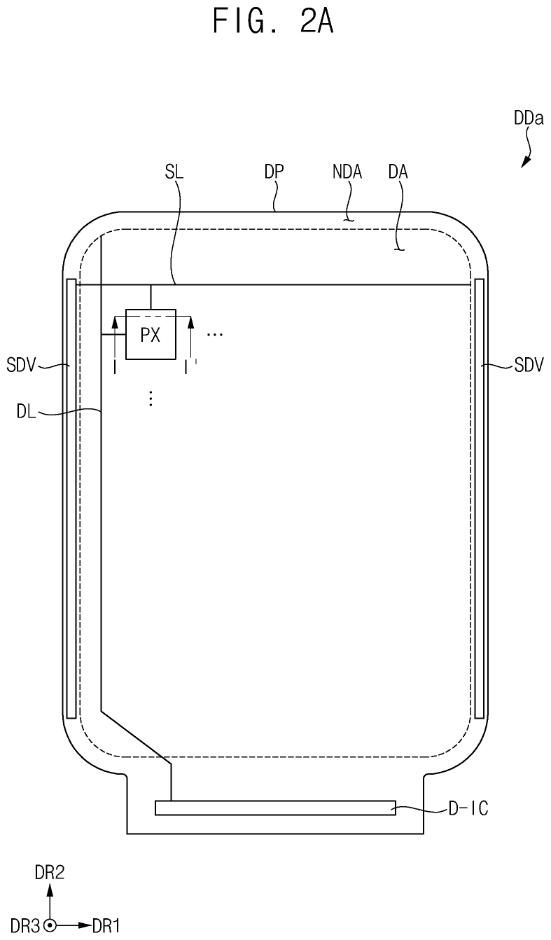

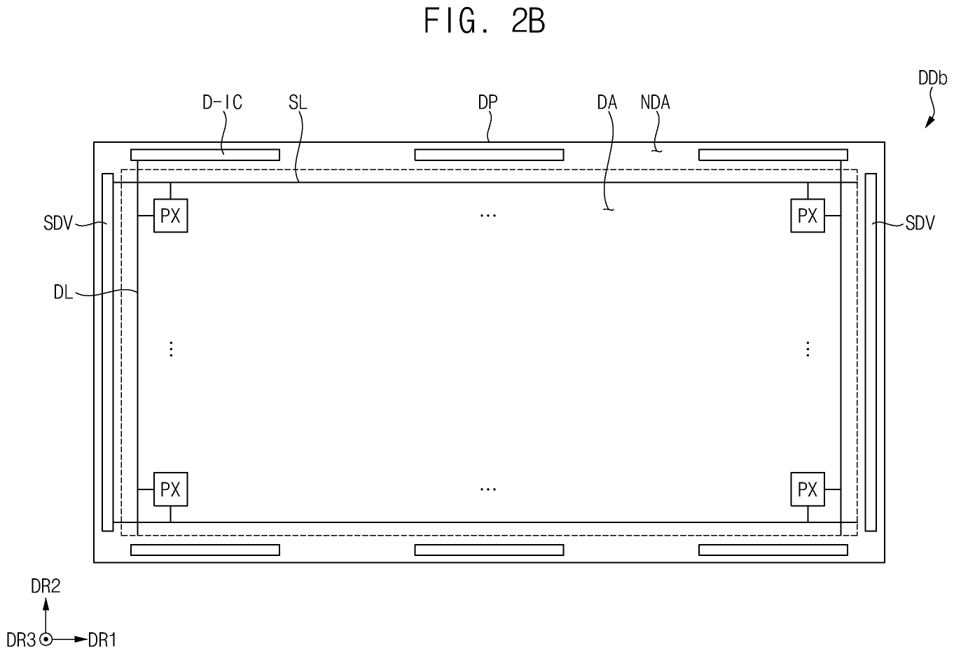

FIG. 2A is a plan view illustrating an example of the display device of FIG. 1. FIG. 2B is a plan view illustrating another example of the display device of FIG. 1.

In this specification, a plane may be defined by the first direction DR1 and the second direction DR2, and a direction normal to the plane may be a third direction DR3. In other words, the third direction DR3 may be perpendicular to each of the first direction DR1 and the second direction DR2. For example, the third direction DR3 may be a thickness direction of the display device. As used herein the “plan view” is a view in the third direction DR3.

Referring to FIGS. 2A and 2B, a display device DDa or DDb may be a device that is activated according to an electrical signal. For example, the display device DDa may be a small-sized display device used in a small-sized electronic device such as a smartphone, a mobile phone, a smart watch, a game console, and a camera. In addition, the display device DDb may be a medium-to-large-sized display device used in a medium-to-large-sized electronic device such as a laptop computer, a tablet PC, a television, a computer monitor, a vehicle monitor, and an external billboard. In FIG. 2A, the display device DDa is illustrated as an example of the small-sized display device, and in FIG. 2B, the display device DDb is illustrated as an example of the medium-to-large-sized display device.

The display device DDa or DDb may include a display area DA and a peripheral area NDA. The display area DA may be an area that displays an image by generating light or by controlling the transmittance of light provided from an external light source. The peripheral area NDA may be located around the display area DA. For example, the peripheral area NDA may surround at least a portion of the display area DA. In an embodiment, the peripheral area NDA may be an area that does not display an image.

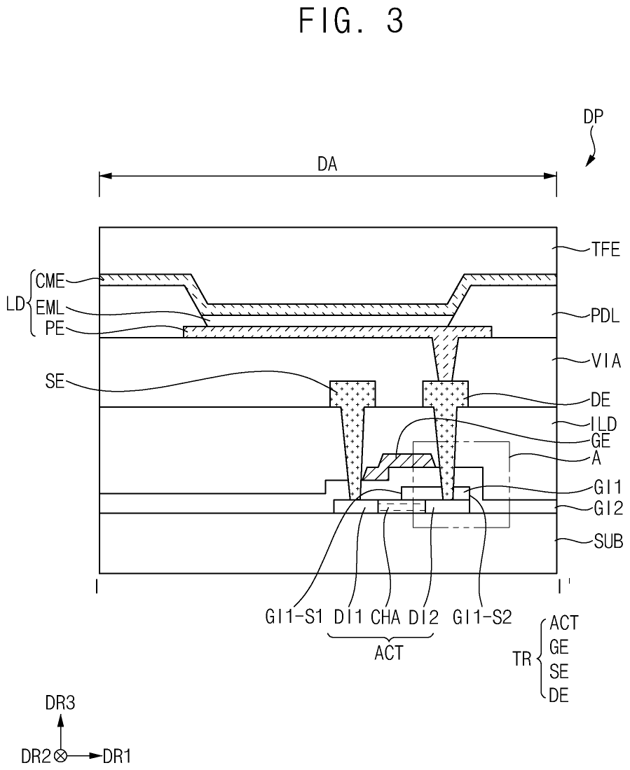

The display device DDa or DDb may include the display panel DP, a scan driver SDV, and a driving chip D-IC, and the display panel DP may include a substrate (SUB, see FIG. 3), the pixels PX, scan lines SL, and the data lines DL.

The substrate may form a base of the display device DDa or DDb. In an embodiment, examples of materials that may be used as the substrate may include glass, quartz, silicon, and a polymer. These may be used alone or in combination with each other. As the display device DDa or DDb includes the display area DA and the peripheral area NDA, the substrate may also include the display area DA and the peripheral area NDA.

The pixels PX may be disposed in the display area DA on the substrate. The pixels PX may be electrically connected to the scan line SL and the data line DL. Here, the scan line SL may correspond to the gate line GL or the emission line ECL of FIG. 1. For example, the pixels PX may be arranged in a matrix form along the first direction DR1 and the second direction DR2. That is, the plurality of pixels PX may be disposed repeatedly in a grid manner defined by rows and columns, the rows being in the first direction DR1 and the columns being in the second direction DR2, with the second direction DR2 being transverse to the first direction DR1.

Each of the pixels PX may include a plurality of sub-pixels. For example, each of the pixels PX may include a first sub-pixel, a second sub-pixel, and a third sub-pixel. Each of the first to third sub-pixels may include a light-emitting element and a pixel driving circuit connected to the light-emitting element. The light-emitting element may emit light. In an embodiment, the first to third sub-pixels may emit light of different wavelength bands from each other. That is, the first to third sub-pixels may emit light of different colors from each other. For example, the first sub-pixel may emit red light, the second sub-pixel may emit green light, and the third sub-pixel may emit blue light. However, the present disclosure is not necessarily limited thereto.

The driving chip D-IC may be disposed in the peripheral area NDA on the substrate. The driving chip D-IC may correspond to the data driver DDV of FIG. 1. That is, the driving chip D-IC may output the data voltage (VDATA, see FIG. 1) to the data line DL. The data voltage may be applied to the pixels PX through the data line DL.

In an embodiment, the driving chip D-IC may be mounted on the substrate. However, the present disclosure is not necessarily limited thereto, and the driving chip D-IC may be disposed on a flexible film coupled to the substrate in the form of a chip on film (COF).

In an embodiment, the display device DDb of FIG. 2B may include a plurality of driving chips D-IC. For example, the driving chips D-IC may be disposed on opposite sides of the display area DA in the second direction DR2. For example, the driving chips D-IC may be disposed along a long side of the display device DDb. However, the present disclosure is not necessarily limited thereto.

The scan driver SDV may be disposed in the peripheral area NDA on the substrate. The scan driver SDV may correspond to the gate driver GDV or the emission driver EDV of FIG. 1. For example, the scan driver SDV may output the gate signal to the scan line SL. The gate signal may be applied to the pixels PX through the scan line SL. For example, the scan driver SDV may output the emission signal to the scan line SL. The emission signal may be applied to the pixels PX through the scan line SL.

In an embodiment, the scan driver SDV may be disposed on opposite sides of the display area DA in the first direction DR1. However, the present disclosure is not necessarily limited thereto.

The number or arrangement relationship of the driving chips D-IC and the number or arrangement relationship of the scan drivers SDV illustrated in FIGS. 2A and 2B are merely examples, and the present disclosure is not necessarily limited thereto.

In addition, in FIG. 2A, the display device DDa is illustrated as having a substantially rectangular planar shape having a short side extending in the first direction DR1 and a long side extending in the second direction DR2, but the present disclosure is not necessarily limited thereto. In addition, in FIG. 2B, the display device DDb is illustrated as having a substantially rectangular planar shape having a long side extending in the first direction DR1 and a short side extending in the second direction DR2, but the present disclosure is not necessarily limited thereto. That is, the planar shape of the display device DDa or DDb may be variously changed according to embodiments.

The descriptions with reference to the drawings below may be equally applied to the display device DDa of FIG. 2A and the display device DDb of FIG. 2B. Hereinafter, for convenience of description, the display device DDa and the display device DDb will be referred to as the display device DD.

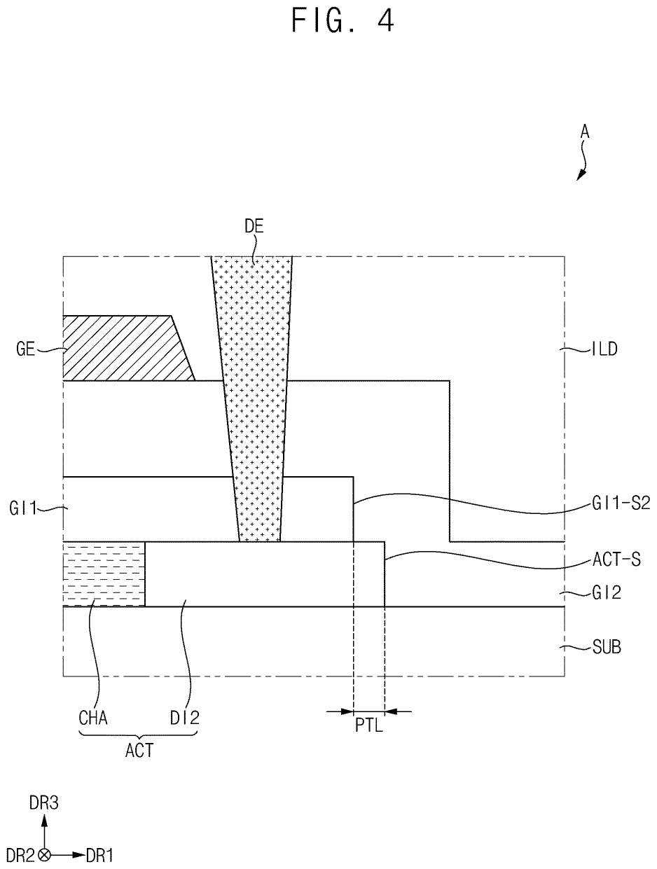

FIG. 3 is a cross-sectional view taken along the line I-I′ of FIG. 2A. For example, FIG. 3 is a cross-sectional view illustrating the cross-sectional structure of the display panel DP in the display area DA. FIG. 4 is an enlarged cross-sectional view of the area A of FIG. 3.

Referring to FIG. 3, the display panel DP may include a substrate SUB, a circuit element layer disposed on the substrate SUB, a light-emitting element layer disposed on the circuit element layer, and an encapsulation layer TFE disposed on the light-emitting element layer.

The circuit element layer may include a thin film transistor TR, a first gate insulating layer GI1, a second gate insulating layer GI2, an inter-layer insulating layer ILD, and a via-insulating layer VIA. The thin film transistor TR may include an active pattern ACT, a gate electrode GE, a source electrode SE, and a drain electrode DE.

The light-emitting element layer may include a light-emitting element LD and a pixel defining layer PDL. The light-emitting element LD may include a pixel electrode PE, a light-emitting layer EML, and a common electrode CME.

A buffer layer may be disposed on the substrate SUB. The buffer layer may prevent diffusion of metal atoms or impurities from the substrate SUB to an upper structure (e.g., the thin film transistor TR, etc.). In addition, the buffer layer may control the heat transfer rate during a crystallization process for forming the active pattern ACT to obtain the substantially uniform active pattern ACT. In addition, when a surface of the substrate SUB is not uniform, the buffer layer may improve flatness of a surface of the substrate SUB. For example, the buffer layer may include an inorganic insulating material. In an embodiment, the buffer layer may be omitted.

The active pattern ACT may be disposed on the substrate SUB. The active pattern ACT may include a silicon semiconductor material, an oxide semiconductor material, an organic semiconductor material, and the like. For example, the silicon semiconductor material may include amorphous silicon, polycrystalline silicon, and the like. For example, the oxide semiconductor material may include at least one oxide of indium (In), gallium (Ga), tin (Sn), zirconium (Zr), vanadium (V), hafnium (Hf), cadmium (Cd), germanium (Ge), chromium (Cr), titanium (Ti), and zinc (Zn).

The active pattern ACT may include a first conductor area DI1, a second conductor area DI2, and a channel area CHA between the first conductor area DI1 and the second conductor area DI2. In other words, each of the first conductor area DI1 and the second conductor area DI2 may be adjacent to the channel area CHA, and the first conductor area DI1 and the second conductor area DI2 may be spaced apart from each other by the channel area CHA.

Each of the first conductor area DI1 and the second conductor area DI2 may be a doped area doped with an impurity, and the channel area CHA may be a non-doped area or an area doped at a lower concentration than the first conductor area DI1 and the second conductor area DI2.

The first gate insulating layer GI1 may be disposed on the active pattern ACT. The first gate insulating layer GI1 may be disposed on an upper surface of the active pattern ACT. An upper surface of the first gate insulating layer GI1 may have a first width (e.g., a length in the first direction DR1), and the upper surface of the active pattern ACT may have a second width greater than the first width. The first gate insulating layer GI1 may include an inorganic insulating material. Examples of the inorganic insulating material that may be used as the first gate insulating layer GI1 may include silicon oxide (SiOₓ), silicon nitride (SiNₓ), silicon oxynitride (SiOₓN_{y}), and the like. These may be used alone or in combination with each other.

In an embodiment, the first gate insulating layer GI1 may overlap the second conductor area DI2 and a portion of the channel area CHA, and may not overlap the first conductor area DI1. That is, the first gate insulating layer GI1 may cover the upper surface of the active pattern ACT in the second conductor area DI2 and the portion of the channel area CHA. The first gate insulating layer GI1 may expose the upper surface of the active pattern ACT in the first conductor area DI1 and another portion of the channel area CHA.

A first side surface GI1-S1 of the first gate insulating layer GI1 may overlap the channel area CHA, and a second side surface GI1-S2 of the first gate insulating layer GI1 opposite to the first side surface GI1-S1 may overlap the second conductor area DI2. In an embodiment, the first gate insulating layer GI1 may overlap a central portion of the channel area CHA. For example, the first side surface GI1-S1 of the first gate insulating layer GI1 may overlap the central portion of the channel area CHA in the first direction DR1. The first side surface GI1-S1 of the first gate insulating layer GI1 may extend beyond the central portion of the channel area CHA, and the first gate insulating layer GI1 may overlap more than a half of the channel area CHA, but the present disclosure is not necessarily limited thereto.

Referring further to FIG. 4, in an embodiment, a side surface ACT-S of the active pattern ACT may protrude further in a direction away from the central portion of the active pattern ACT, with respect to the second side surface GI1-S2 of the first gate insulating layer GI1. In other words, the second side surface GI1-S2 of the first gate insulating layer GI1 may be recessed toward the central portion of the active pattern ACT relative to the side surface ACT-S of the active pattern ACT. For example, the side surface ACT-S of the active pattern ACT may overlap the second conductor area DI2. Accordingly, the side surface ACT-S of the active pattern ACT and the second side surface GI1-S2 of the first gate insulating layer GI1 may form a step structure. For example, a protruding length PTL by which the side surface ACT-S of the active pattern ACT protrudes more than the second side surface GI1-S2 of the first gate insulating layer GI1 may be about 0.05 micrometers to about 0.5 micrometers, but the present disclosure is not necessarily limited thereto.

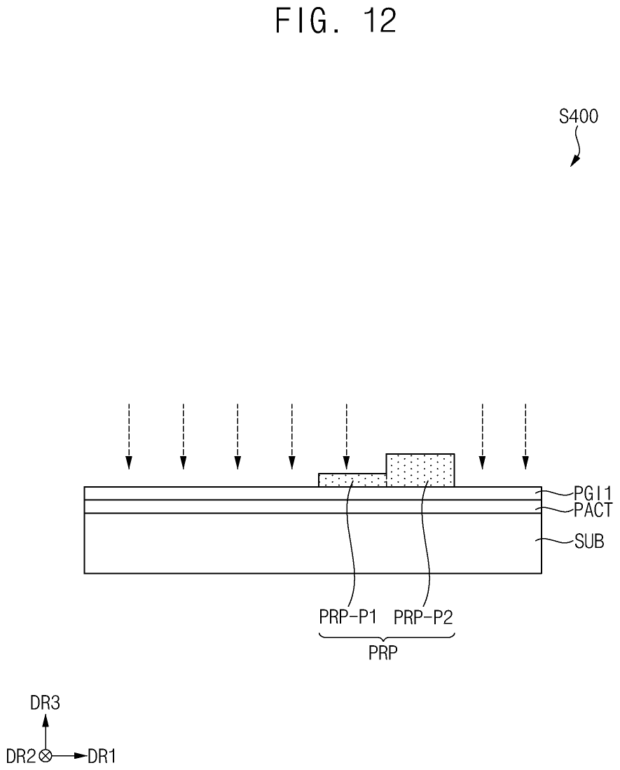

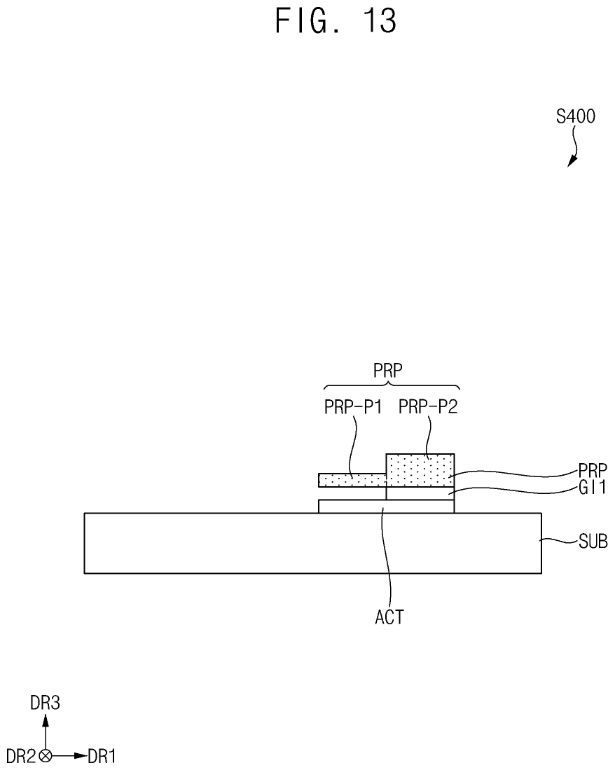

In an embodiment, the side surface ACT-S of the active pattern ACT and the second side surface GI1-S2 of the first gate insulating layer GI1 may be aligned parallel to each other along a thickness direction (e.g., the third direction DR3). The active pattern ACT and the first gate insulating layer GI1 may be simultaneously formed through the same etching process. If a cleaning process is not performed after the etching process, the side surface ACT-S of the active pattern ACT and the second side surface GI1-S2 of the first gate insulating layer GI1 may be aligned parallel to each other along the thickness direction (e.g., the third direction DR3). A detailed description thereof is described below with reference to FIGS. 12 and 13.

The second gate insulating layer GI2 may be disposed on the substrate SUB, the active pattern ACT, and the first gate insulating layer GI1. The second gate insulating layer GI2 may cover the active pattern ACT and the first gate insulating layer GI1 on the substrate SUB. In an embodiment, the second gate insulating layer GI2 may extend along profiles of the active pattern ACT and the first gate insulating layer GI1 with a substantially uniform thickness. Accordingly, the second gate insulating layer GI2 may have a step. However, the present disclosure is not necessarily limited thereto. The second gate insulating layer GI2 may include an inorganic insulating material. Examples of the inorganic insulating material that may be used as the second gate insulating layer GI2 may include silicon oxide (SiOₓ), silicon nitride (SiNₓ), silicon oxynitride (SiOₓN_{y}), and the like. These may be used alone or in combination with each other.

The gate electrode GE may be disposed on the second gate insulating layer GI2. The gate electrode GE may overlap the channel area CHA of the active pattern ACT in a plan view. In an embodiment, the gate electrode GE may be disposed along a profile of the second gate insulating layer GI2. As the gate electrode GE is disposed along the profile of the second gate insulating layer GI2 having a step, the gate electrode GE may also have a step. In an embodiment, the gate electrode GE may overlap the first side surface GI1-S1 of the first gate insulating layer GI1 in a plan view, and may not overlap the second side surface GI1-S2 of the first gate insulating layer GI1.

In an embodiment, a thickness of a gate insulating layer between the second conductor area DI2 and the gate electrode GE may be greater than a thickness of a gate insulating layer between the first conductor area DI1 and the gate electrode GE. The first gate insulating layer GI1 and the second gate insulating layer GI2 may be disposed between the second conductor area DI2 and the gate electrode GE, and only the second gate insulating layer GI2 may be disposed between the first conductor area DI1 and the gate electrode GE. In this case, a sum of the thickness of the first gate insulating layer GI1 and the thickness of the second gate insulating layer GI2 between the second conductor area DI2 and the gate electrode GE may be greater than the thickness of the second gate insulating layer GI2 between the first conductor area DI1 and the gate electrode GE. Accordingly, the concentration of the electric field in the second conductor area DI2 may be reduced, the hot carrier phenomenon may be reduced, and the device (or element) reliability of the thin film transistor TR may be improved.

The gate electrode GE may include a conductive material such as a metal, an alloy, a conductive metal nitride, a conductive metal oxide, a transparent conductive oxide, and the like. Examples of the conductive material may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and the like. These may be used alone or in combination with each other.

The inter-layer insulating layer ILD may be disposed on the second gate insulating layer GI2. The inter-layer insulating layer ILD may cover the gate electrode GE. In an embodiment, the inter-layer insulating layer ILD may sufficiently cover the gate electrode GE on the second gate insulating layer GI2 and may have a substantially flat upper surface without forming a step around the gate electrode GE. For instance, the flattening second gate insulating layer GI2 provides a same distance for a top surface of the second gate insulating layer GI2 from the substrate. Accordingly, the inter-layer insulating layer ILD may flatten the step of the second gate insulating layer GI2 and the gate electrode GE, but the present disclosure is not necessarily limited thereto. The inter-layer insulating layer ILD may include an inorganic insulating material. Examples of the inorganic insulating material that may be used as the inter-layer insulating layer ILD may include silicon oxide (SiOₓ), silicon nitride (SiNₓ), silicon oxynitride (SiOₓN_{y}), and the like. These may be used alone or in combination with each other.

The source electrode SE and the drain electrode DE may be disposed on the inter-layer insulating layer ILD. In an embodiment, the source electrode SE may be connected to the first conductor area DI1 of the active pattern ACT through a first contact hole penetrating the inter-layer insulating layer ILD and the second gate insulating layer GI2, and the drain electrode DE may be connected to the second conductor area DI2 of the active pattern ACT through a second contact hole penetrating the inter-layer insulating layer ILD, the second gate insulating layer GI2, and the first gate insulating layer GI1. That is, the drain electrode DE may penetrate the first gate insulating layer GI1, and the source electrode SE may not penetrate the first gate insulating layer GI1. Each of the source electrode SE and the drain electrode DE may include a conductive material such as a metal, an alloy, a conductive metal nitride, a conductive metal oxide, a transparent conductive oxide, and the like. These may be used alone or in combination with each other.

Accordingly, the thin film transistor TR including the active pattern ACT, the gate electrode GE, the source electrode SE, and the drain electrode DE may be disposed on the substrate SUB.

The via-insulating layer VIA may be disposed on the inter-layer insulating layer ILD. The via-insulating layer VIA may cover the source electrode SE and the drain electrode DE. For example, the via-insulating layer VIA may be disposed with a relatively thick thickness so as to sufficiently cover the source electrode SE and the drain electrode DE. The via-insulating layer VIA may have a flat upper surface. The via-insulating layer VIA may include an organic insulating material. Examples of the organic insulating material that may be used as the via-insulating layer VIA may include a polyacryl-based resin, a polyimide-based resin, a polyamide-based resin, a siloxane-based resin, an epoxy-based resin, and the like. These may be used alone or in combination with each other.

The pixel electrode PE may be disposed on the via-insulating layer VIA. The pixel electrode PE may be connected to the source electrode SE or the drain electrode DE through a contact hole penetrating the via-insulating layer VIA. For example, the pixel electrode PE may be connected to the drain electrode DE through the contact hole penetrating the via-insulating layer VIA. Accordingly, the pixel electrode PE may be electrically connected to the thin film transistor TR. The pixel electrode PE may include a conductive material such as a metal, an alloy, a conductive metal nitride, a conductive metal oxide, a transparent conductive oxide, and the like. These may be used alone or in combination with each other. For example, the pixel electrode PE may operate as an anode of the light-emitting element LD.

The pixel defining layer PDL may be disposed on the via-insulating layer VIA. The pixel defining layer PDL may cover an edge of the pixel electrode PE, and may define a pixel opening exposing an upper surface of the pixel electrode PE. The pixel defining layer PDL may include an organic insulating material and/or an inorganic insulating material. In an embodiment, the pixel defining layer PDL may further include an inorganic material or an organic material including a light-blocking material. For example, the light-blocking material may include a black pigment, a black dye, carbon black, and the like. These may be used alone or in combination with each other.

The light-emitting layer EML may be disposed on the pixel electrode PE. The light-emitting layer EML may be disposed in the pixel opening defined by the pixel defining layer PDL. The light-emitting layer EML may emit light having a specific color (e.g., red, green, or blue). In an embodiment, the light-emitting layer EML may include at least one of an organic light-emitting material and a quantum dot. For example, the light-emitting layer EML may have a single-layer structure including one light-emitting structure. However, the present disclosure is not necessarily limited thereto, and the light-emitting layer EML may have a tandem structure including a plurality of light-emitting structures.

The common electrode CME may be disposed on the pixel defining layer PDL and the light-emitting layer EML. The common electrode CME may cover the pixel defining layer PDL and the light-emitting layer EML. For example, the common electrode CME may extend along profiles of the pixel defining layer PDL and the light-emitting layer EML with a substantially uniform thickness. The common electrode CME may include a conductive material such as a metal, an alloy, a conductive metal nitride, a conductive metal oxide, a transparent conductive oxide, and the like. These may be used alone or in combination with each other. For example, the common electrode CME may operate as a cathode of the light-emitting element LD.

Accordingly, the light-emitting element LD including the pixel electrode PE, the light-emitting layer EML, and the common electrode CME may be disposed on the via-insulating layer VIA.

The encapsulation layer TFE may be disposed on the common electrode CME. The encapsulation layer TFE may prevent impurities, moisture, and the like from penetrating into the light-emitting element LD from outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), and the like. These may be used alone or in combination with each other. For example, the organic encapsulation layer may include a polymer cured product such as polyacrylate. In an embodiment, the encapsulation layer TFE may include a first inorganic encapsulation layer, an organic encapsulation layer disposed on the first inorganic encapsulation layer, and a second inorganic encapsulation layer disposed on the organic encapsulation layer, but the present disclosure is not necessarily limited thereto.

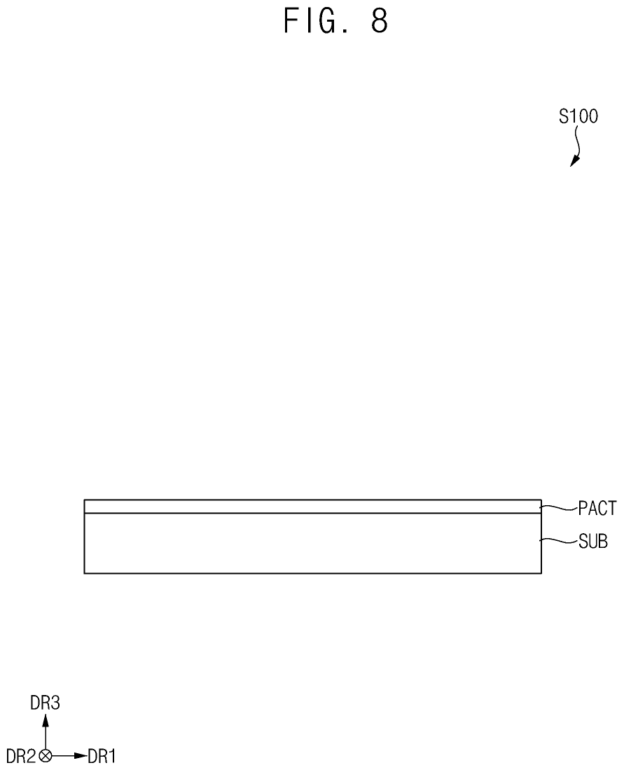

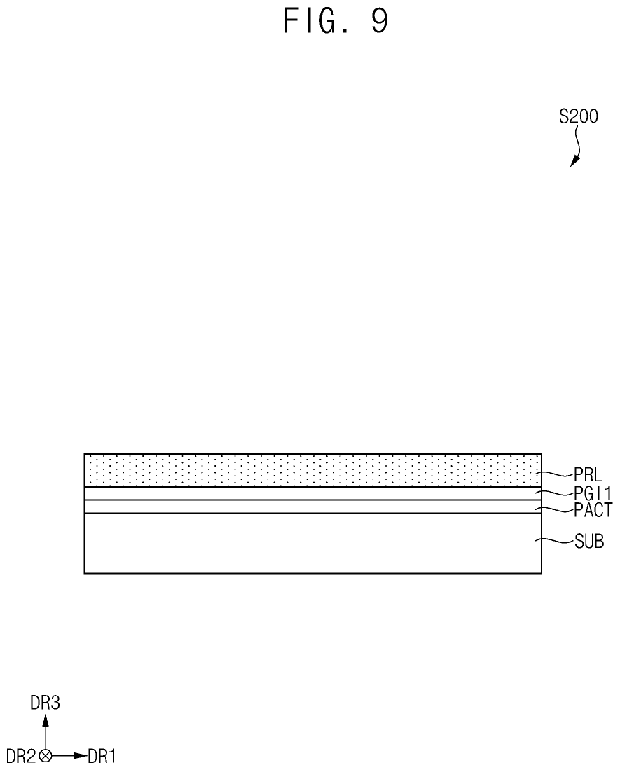

According to the present disclosure, the first gate insulating layer GI1 and the active pattern ACT may be simultaneously formed through the same etching process. A preliminary semiconductor layer (PACT, see FIG. 8) may be formed on the substrate SUB, a preliminary insulating layer (PGI1, see FIG. 9) and a photoresist layer (PRL, see FIG. 9) may be formed on the preliminary semiconductor layer, and then the preliminary semiconductor layer and the preliminary insulating layer may be simultaneously etched. Therefore, in the process of forming the active pattern ACT, the preliminary semiconductor layer may not directly contact the photoresist layer. Accordingly, it is possible to prevent a problem in which an interface (or an upper surface) of the preliminary semiconductor layer or the active pattern ACT is contaminated by the photoresist layer. A detailed description thereof is described below with reference to FIGS. 9 to 13.

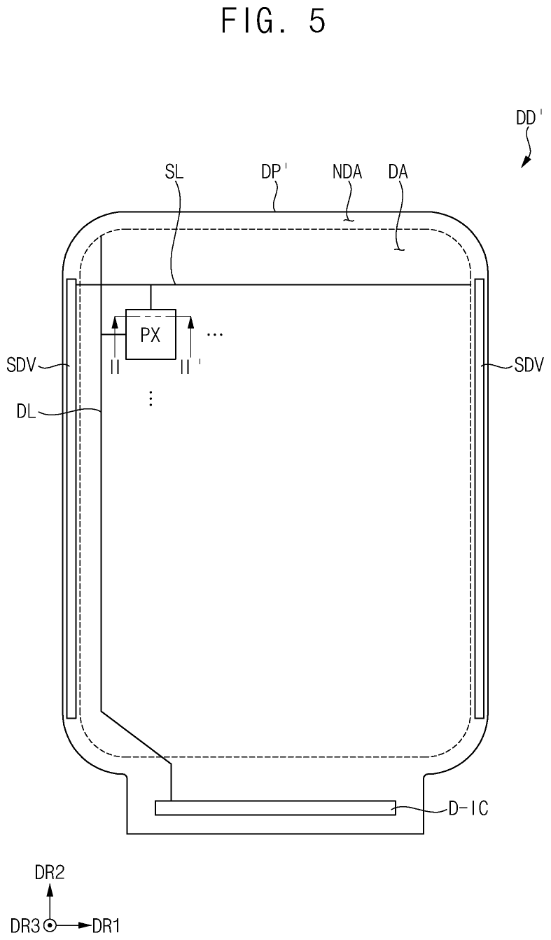

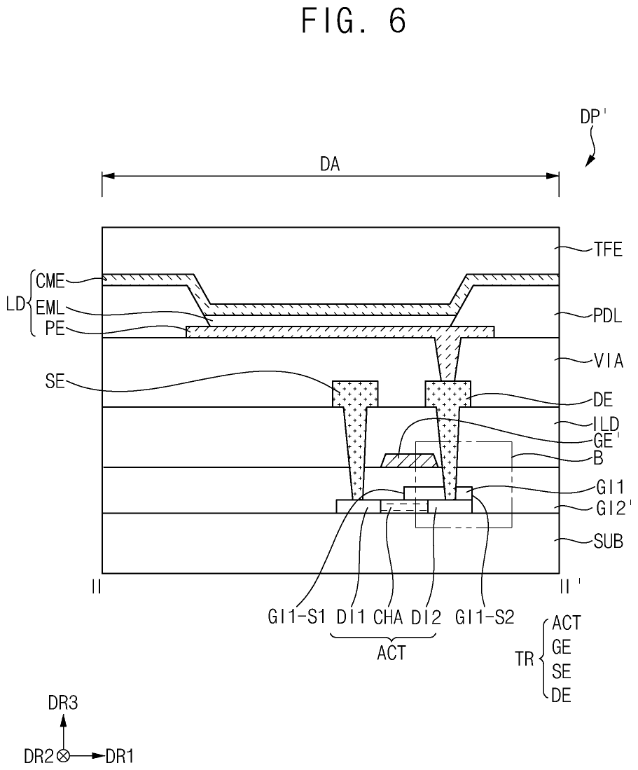

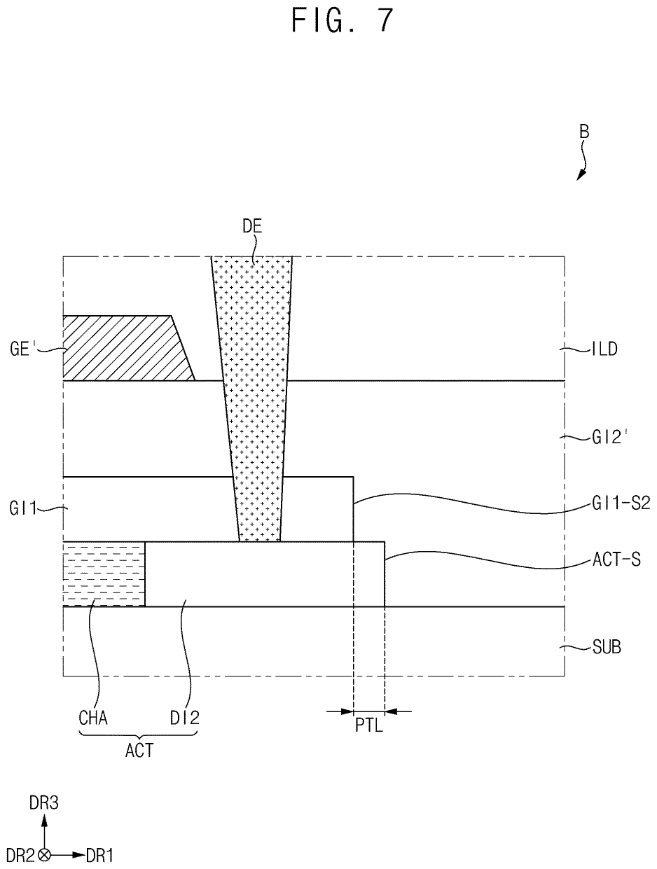

FIG. 5 is a plan view illustrating a display device according to an embodiment of the present disclosure. FIG. 6 is a cross-sectional view taken along the line II-II′ of FIG. 5. FIG. 7 is enlarged cross-sectional view of the area B of FIG. 6.

Referring to FIGS. 5, 6, and 7, a display device DD′ according to an embodiment of the present disclosure may include a display panel DP′, a scan driver SDV, and a driving chip D-IC, and the display panel DP′ may include pixels PX, scan lines SL, and data lines DL. As illustrated in FIG. 6, the display panel DP′ may include a substrate SUB, a thin film transistor TR, a first gate insulating layer GI1, a second gate insulating layer GI2′, an inter-layer insulating layer ILD, a via-insulating layer VIA, a light-emitting element LD, a pixel defining layer PDL, and an encapsulation layer TFE. The thin film transistor TR may include an active pattern ACT, a gate electrode GE′, a source electrode SE, and a drain electrode DE.

The display device DD′ may be substantially the same as the display device DD described above with reference to FIGS. 1 to 4, except that the second gate insulating layer GI2′ has a substantially flat upper surface. Hereinafter, redundant descriptions of the display device DD described above with reference to FIGS. 1 to 4 are omitted or simplified.

The active pattern ACT may be disposed on the substrate SUB. The active pattern ACT may include a first conductor area DI1, a second conductor area DI2, and a channel area CHA between the first conductor area DI1 and the second conductor area DI2.

The first gate insulating layer GI1 may be disposed on the active pattern ACT. The first gate insulating layer GI1 may be disposed on an upper surface of the active pattern ACT. In an embodiment, the first gate insulating layer GI1 may overlap the second conductor area DI2 and a portion of the channel area CHA, and may not overlap the first conductor area DI1. The first gate insulating layer GI1 may be formed by etching simultaneously with the active pattern ACT.

A first side surface GI1-S1 of the first gate insulating layer GI1 may overlap the channel area CHA, and a second side surface GI1-S2 of the first gate insulating layer GI1 may overlap the second conductor area DI2. In an embodiment, the first gate insulating layer GI1 may overlap a central portion of the channel area CHA. For example, the first side surface GI1-S1 of the first gate insulating layer GI1 may overlap the central portion of the channel area CHA in the first direction DR1. The first side surface GI1-S1 of the first gate insulating layer GI1 may extend beyond the central portion of the channel area CHA, and the first gate insulating layer GI1 may overlap more than a half of the channel area CHA, but the present disclosure is not necessarily limited thereto.

As illustrated in FIG. 7, in an embodiment, a side surface ACT-S of the active pattern ACT may protrude further in a direction away from the central portion of the active pattern ACT, with respect to the second side surface GI1-S2 of the first gate insulating layer GI1. For example, the side surface ACT-S of the active pattern ACT may correspond to a side surface of the second conductor area DI2. Accordingly, the side surface ACT-S of the active pattern ACT and the second side surface GI1-S2 of the first gate insulating layer GI1 may form a step structure. However, the present disclosure is not necessarily limited thereto. In an embodiment, the side surface ACT-S of the active pattern ACT and the second side surface GI1-S2 of the first gate insulating layer GI1 may be aligned parallel to each other along a thickness direction (e.g., the third direction DR3).

The second gate insulating layer GI2′ may be disposed on the substrate SUB, the active pattern ACT, and the first gate insulating layer GI1. The second gate insulating layer GI2′ may cover the active pattern ACT and the first gate insulating layer GI1 on the substrate SUB. In an embodiment, the second gate insulating layer GI2′ may have a substantially flat upper surface without forming a step around the active pattern ACT and the first gate insulating layer GI1. In this case, the upper surface of the second gate insulating layer GI2′ may be flattened through a polishing process, but the present disclosure is not necessarily limited thereto.

The gate electrode GE′ may be disposed on the second gate insulating layer GI2′ The gate electrode GE′ may overlap the channel area CHA of the active pattern ACT in a plan view. In an embodiment, as the second gate insulating layer GI2′ has the substantially flat upper surface, the gate electrode GE′ may also have a substantially flat upper surface. In an embodiment, the gate electrode GE′ may overlap the first side surface GI1-S1 of the first gate insulating layer GI1 in a plan view, and may not overlap the second side surface GI1-S2.

In an embodiment, when the second gate insulating layer GI2′ has the substantially flat upper surface, a thickness of a gate insulating layer between the second conductor area DI2 and the gate electrode GE′ may be substantially the same as a thickness of a gate insulating layer between the first conductor area DI1 and the gate electrode GE′. That is, a sum of the thickness of the first gate insulating layer GI1 and the thickness of the second gate insulating layer GI2′ between the second conductor area DI2 and the gate electrode GE′ may be substantially the same as the thickness of the second gate insulating layer GI2′ between the first conductor area DI1 and the gate electrode GE′.

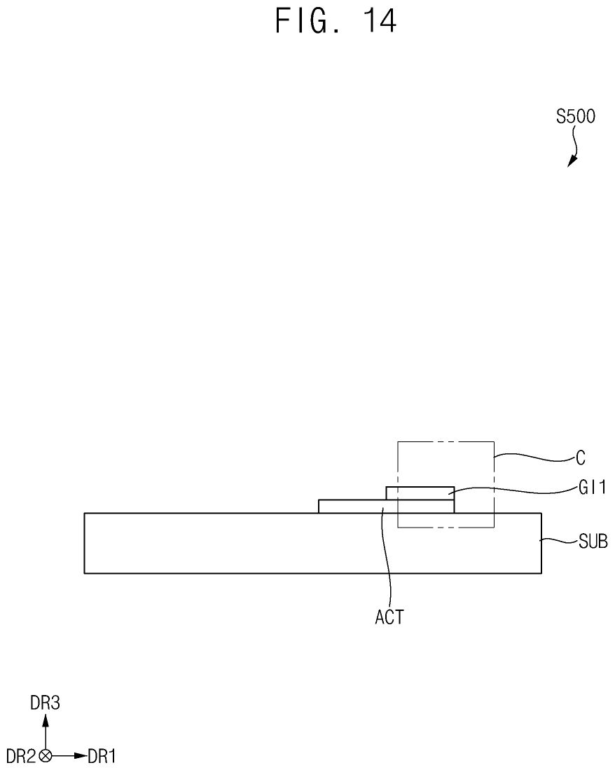

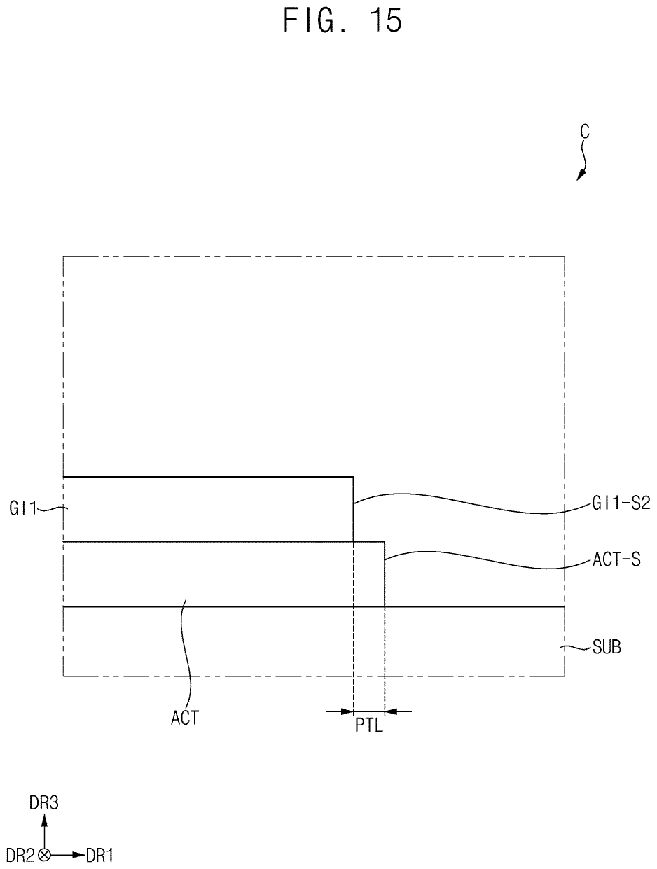

FIGS. 8, 9, 10, 11, 12, 13, 14, 15, 16, 17, 18, and 19 are cross-sectional views illustrating a method of manufacturing a display device according to an embodiment of the present disclosure. For example, FIG. 15 is an enlarged cross-sectional view of the area C of FIG. 14. The method of manufacturing the display device described below with reference to FIGS. 8 to 19 may be a method of manufacturing the display device DD described above with reference to FIGS. 1 to 4. Hereinafter, redundant descriptions of the display device DD described above with reference to FIGS. 1 to 4 are omitted or simplified.

Referring to FIG. 8, a preliminary semiconductor layer PACT may be formed on a substrate SUB (S100). The preliminary semiconductor layer PACT may include a silicon semiconductor material, an oxide semiconductor material, an organic semiconductor material, and the like. In an embodiment, the preliminary semiconductor layer PACT may include a silicon semiconductor material. For example, the silicon semiconductor material may include amorphous silicon, polycrystalline silicon, and the like.

Referring to FIG. 9, a preliminary insulating layer PGI1 may be formed on the preliminary semiconductor layer PACT, and a photoresist layer PRL may be formed on the preliminary insulating layer PGI1 (S200). The preliminary semiconductor layer PACT may be spaced apart from the photoresist layer PRL by the preliminary insulating layer PGI1. That is, the preliminary semiconductor layer PACT may not directly contact the photoresist layer PRL.

The preliminary insulating layer PGI1 may include an inorganic insulating material. Examples of the inorganic insulating material that may be used as the preliminary insulating layer PGI1 may include silicon oxide (SiOₓ), silicon nitride (SiNₓ), silicon oxynitride (SiOₓN_{y}), and the like.

The photoresist layer PRL may include a photosensitive organic material. In an embodiment, the photoresist layer PRL may include a positive photosensitive organic material, but the present disclosure is not necessarily limited thereto.

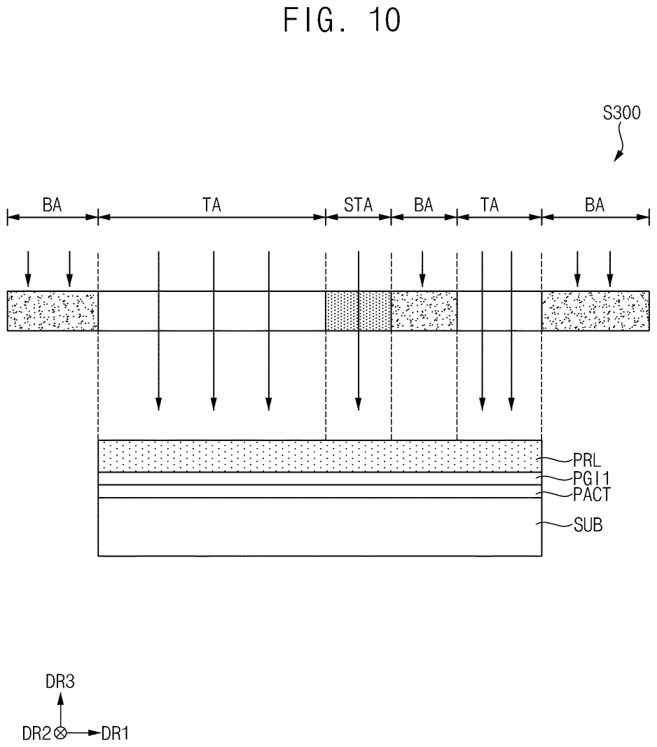

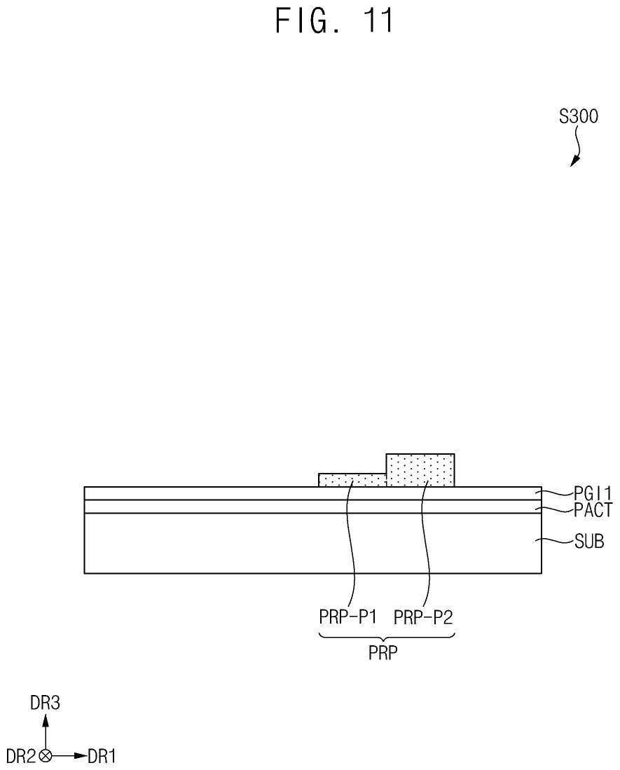

Referring to FIGS. 10 and 11, a photoresist pattern PRP may be formed by exposing and developing the photoresist layer PRL using a photomask PM (S300).

As illustrated in FIG. 10, the photomask PM may be positioned on the photoresist layer PRL. The photomask PM may include a light-blocking portion BA, a first light-transmitting portion TA, and a second light-transmitting portion STA. The light-blocking portion BA may be an area in which incident light incident on the photomask PM is blocked, and each of the first light-transmitting portion TA and the second light-transmitting portion STA may be an area in which the incident light incident on the photomask PM is transmitted.

In an embodiment, the first light-transmitting portion TA may have a first light transmittance, and the second light-transmitting portion STA may have a second light transmittance lower than the first light transmittance. For example, the first light-transmitting portion TA may transmit the incident light as it is, and the second light-transmitting portion STA may transmit only a portion of the incident light. For example, the second light-transmitting portion STA may transmit about 50% or less of the incident light incident on the second light-transmitting portion STA. That is, the photomask PM may be a halftone mask.

Accordingly, the incident light may not reach an area of the photoresist layer PRL overlapping the light-blocking portion BA. In addition, most of the incident light may reach an area of the photoresist layer PRL overlapping the first light-transmitting portion TA, and only a portion of the incident light may reach an area of the photoresist layer PRL overlapping the second light-transmitting portion STA.

For example, when the photoresist layer PRL includes a positive photosensitive organic material, a portion in which light is blocked may remain in a cured state and may not be dissolved in a developer. In this case, a portion of the photoresist layer PRL exposed to light may be selectively removed, and a portion of the photoresist layer PRL in which light is blocked may not be removed.

That is, a first portion of the photoresist layer PRL overlapping the light-blocking portion BA may remain without being removed by the developer. A second portion of the photoresist layer PRL overlapping the first light-transmitting portion TA may be completely removed by the developer. A third portion of the photoresist layer PRL overlapping the second light-transmitting portion STA may be partially removed by the developer. Accordingly, as illustrated in FIG. 11, the photoresist pattern PRP may be formed. The photoresist pattern PRP may include a first portion PRP-P1 having a relatively small thickness (e.g., a length in the third direction DR3), and a second portion PRP-P2 connected to the first portion PRP-P1 and having a relatively large thickness.

In FIGS. 10 and 11, a case where the photoresist layer PRL includes a positive photosensitive organic material is described as an example, but the present disclosure is not necessarily limited thereto. For example, the photoresist layer PRL may include a negative photosensitive organic material. In this case, an area of the photoresist layer PRL corresponding to the light-blocking portion BA of the photomask PM and an area of the photoresist layer PRL corresponding to the first light-transmitting portion TA of the photomask PM may be reversed.

Referring to FIGS. 12 and 13, the preliminary semiconductor layer PACT and the preliminary insulating layer PGI1 may be simultaneously etched using the photoresist pattern PRP as an etching mask to form an active pattern ACT and a first gate insulating layer GI1, respectively (S400).

In an area exposed by the photoresist pattern PRP, the preliminary semiconductor layer PACT and the preliminary insulating layer PGI1 may be removed by an etching process. That is, a first portion of the preliminary semiconductor layer PACT and a first portion of the preliminary insulating layer PGI1 that do not overlap the photoresist pattern PRP in a plan view may be removed.

A second portion of the preliminary insulating layer PGI1 overlapping the first portion PRP-P1 of the photoresist pattern PRP having the relatively small thickness in a plan view may be removed by the etching process. In an embodiment, as illustrated in FIGS. 12 and 13, the second portion of the preliminary insulating layer PGI1 overlapping the first portion PRP-P1 of the photoresist pattern PRP in a plan view may be removed, and a second portion of the preliminary semiconductor layer PACT overlapping the first portion PRP-P1 of the photoresist pattern PRP in a plan view may remain. In an embodiment, the etching process may be a dry etching process.

A third portion of the preliminary insulating layer PGI1 and a third portion of the preliminary semiconductor layer PACT overlapping the second portion PRP-P2 of the photoresist pattern PRP having the relatively large thickness in a plan view may remain without being removed by the etching process. Accordingly, the preliminary semiconductor layer PACT and the preliminary insulating layer PGI1 may be simultaneously patterned through the etching process. That is, the preliminary semiconductor layer PACT may be patterned to form the active pattern ACT, and the preliminary insulating layer PGI1 may be patterned to form the first gate insulating layer GI1. The first gate insulating layer GI1 may be formed on an upper surface of the active pattern ACT and may partially overlap the active pattern ACT.

In an embodiment, after the etching process, one side surface of the active pattern ACT and one side surface of the first gate insulating layer GI1 corresponding the one side surface of the active pattern ACT may be aligned parallel to each other along a thickness direction (e.g., the third direction DR3).

According to the present disclosure, since the preliminary insulating layer PGI1 and the photoresist layer PRL are formed on the preliminary semiconductor layer PACT and the preliminary semiconductor layer PACT and the preliminary insulating layer PGI1 are simultaneously etched, in the process of forming the active pattern ACT, the preliminary semiconductor layer PACT may not directly contact the photoresist layer PRL or the photoresist pattern PRP. Accordingly, it is possible to prevent a problem in which an interface (or an upper surface) of the preliminary semiconductor layer PACT is contaminated when the preliminary semiconductor layer PACT directly contacts the photoresist layer PRL (or the photoresist pattern PRP). As a result, it is possible to prevent a problem in which an off current of a thin film transistor increases when the interface (or the upper surface) of the preliminary semiconductor layer PACT is contaminated, and device (or element) characteristics of the thin film transistor may be improved.

In FIGS. 10 and 11, a case where the photomask PM is a halftone mask is described as an example, but the present disclosure is not necessarily limited thereto. For example, after forming a first photoresist pattern using a first photomask having the light-blocking portion BA and the first light-transmitting portion TA, the preliminary semiconductor layer PACT and the preliminary insulating layer PGI1 may be primarily etched using the first photoresist pattern as a mask. Thereafter, after forming a second photoresist pattern using a second photomask different from the first photomask, a portion of the preliminary insulating layer PGI1 may be secondarily etched using the second photoresist pattern as a mask, thereby forming the first gate insulating layer GI1.

Referring to FIGS. 13, 14, and 15, the photoresist pattern PRP may be removed, and a cleaning process using hydrofluoric acid (HF) may be performed (S500).

After the active pattern ACT and the first gate insulating layer GI1 are formed through the etching process, the photoresist pattern PRP remaining on the first gate insulating layer GI1 may be removed. For example, the photoresist pattern PRP may be removed by a strip process.

In an embodiment, after removing the photoresist pattern PRP, the cleaning process using HF may be performed. Through the cleaning process, an oxide layer remaining on an upper surface of the active pattern ACT may be removed. As illustrated in FIG. 15, while the cleaning process using HF is performed, a side surface of the first gate insulating layer GI1 (e.g., a second side surface GI1-S2) may be etched. In this case, with respect to the cleaning process, an etch rate of the active pattern ACT may be lower than an etch rate of the first gate insulating layer GI1. That is, an etch rate of the active pattern ACT with respect to HF may be lower than an etch rate of the first gate insulating layer GI1 with respect to HF.

Accordingly, while the cleaning process is performed, a portion of the side surface of the first gate insulating layer GI1 may be removed. In contrast, while the cleaning process is performed, the active pattern ACT may not be removed. As a result, a side surface ACT-S of the active pattern ACT may protrude further in a direction away from a central portion of the active pattern ACT with respect to a side surface (e.g., the second side surface GI1-S2) of the first gate insulating layer GI1. In an embodiment, the cleaning process may be omitted.

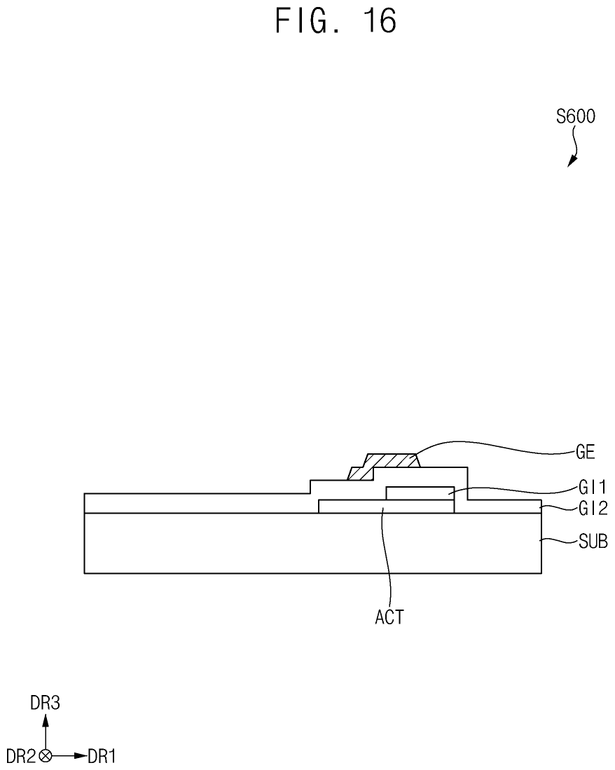

Referring to FIG. 16, a second gate insulating layer GI2 may be formed on the substrate SUB, the active pattern ACT, and the first gate insulating layer GI1, and a gate electrode GE may be formed on the second gate insulating layer GI2 (S600).

The second gate insulating layer GI2 may cover the active pattern ACT and the first gate insulating layer GI1 on the substrate SUB. In an embodiment, the second gate insulating layer GI2 may be formed with a substantially uniform thickness along profiles of the active pattern ACT and the first gate insulating layer GI1. Accordingly, the second gate insulating layer GI2 may have a step. The gate electrode GE may be formed on the second gate insulating layer GI2 along the profile of the second gate insulating layer GI2. As the gate electrode GE is disposed along the profile of the second gate insulating layer GI2 having the step, the gate electrode GE may also have a step.

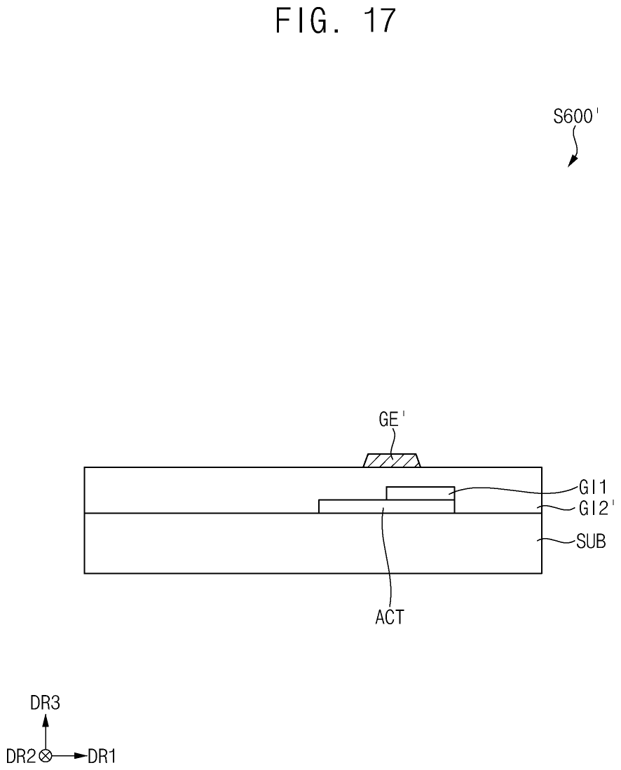

Referring to FIG. 17, a second gate insulating layer GI2′ may be formed to have a substantially flat upper surface, and a gate electrode GE′ may be formed on an upper surface of the second gate insulating layer GI2′ (S600′).

For example, after applying the second gate insulating layer GI2′ so as to cover the active pattern ACT and the first gate insulating layer GI1 on the substrate SUB, the upper surface of the second gate insulating layer GI2′ may be flattened through a polishing process. For example, the polishing process may be a chemical mechanical polishing (CMP) process in which mechanical removal processing and chemical removal processing are combined into one processing method. Accordingly, the second gate insulating layer GI2′ may have the substantially flat upper surface without forming a step around the active pattern ACT and the first gate insulating layer GI1. As the second gate insulating layer GI2′ has the substantially flat upper surface, the gate electrode GE′ may also be formed to have a substantially flat upper surface.

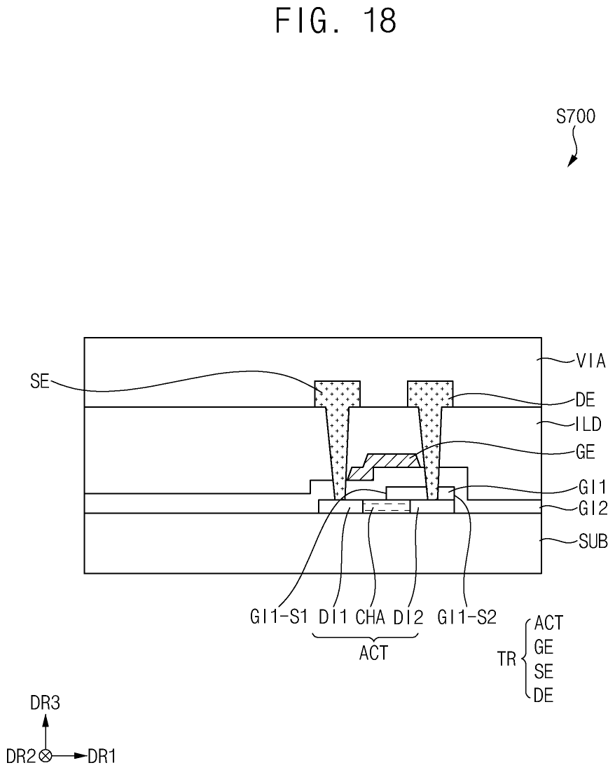

Referring to FIG. 18, a portion of the active pattern ACT may be doped, and an inter-layer insulating layer ILD may be formed on the second gate insulating layer GI2 (S700).

Through a process of doping the portion of the active pattern ACT, the active pattern ACT may have a first conductor area DI1, a second conductor area DI2, and a channel area CHA between the first conductor area DI1 and the second conductor area DI2. Each of the first conductor area DI1 and the second conductor area DI2 may be a doped area doped with an impurity. In the process of doping the active pattern ACT, the gate electrode GE may function as a mask.

The inter-layer insulating layer ILD may cover the gate electrode GE on the second gate insulating layer GI2. In an embodiment, the inter-layer insulating layer ILD may have a substantially flat upper surface without forming a step around the gate electrode GE. Accordingly, the inter-layer insulating layer ILD may flatten the step of the second gate insulating layer GI2 and the gate electrode GE.

A source electrode SE and a drain electrode DE may be formed on the inter-layer insulating layer ILD. The source electrode SE may be connected to the first conductor area DI1 of the active pattern ACT through a first contact hole penetrating the inter-layer insulating layer ILD and the second gate insulating layer GI2, and the drain electrode DE may be connected to the second conductor area DI2 of the active pattern ACT through a second contact hole penetrating the inter-layer insulating layer ILD, the second gate insulating layer GI2, and the first gate insulating layer GI1. That is, the drain electrode DE may penetrate the first gate insulating layer GI1, and the source electrode SE may not penetrate the first gate insulating layer GI1.

A via-insulating layer VIA may be formed on the inter-layer insulating layer ILD. The via-insulating layer VIA may cover the source electrode SE and the drain electrode DE.

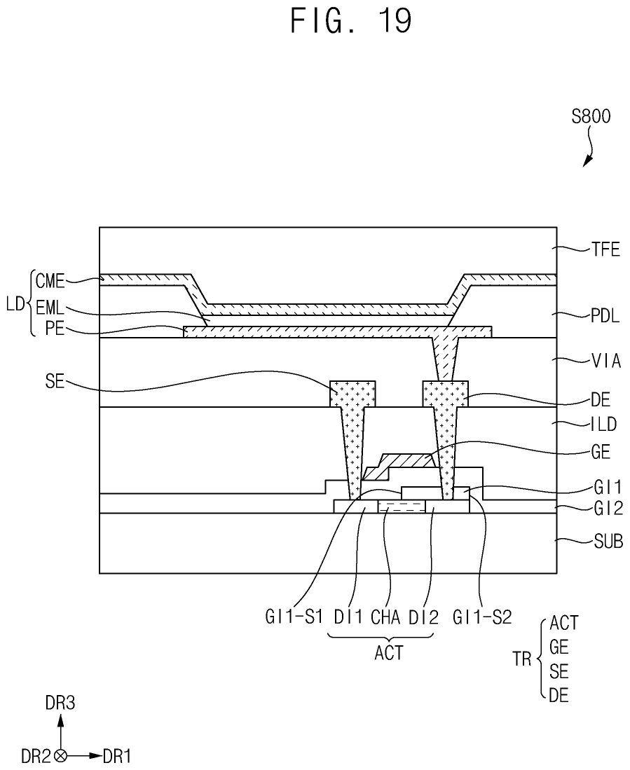

Referring to FIG. 19, a light-emitting element LD may be formed on the via-insulating layer VIA, and an encapsulation layer TFE may be formed on the light-emitting element LD (S800).

A pixel electrode PE may be formed on the via-insulating layer VIA. The pixel electrode PE may be connected to the source electrode SE or the drain electrode DE through a contact hole penetrating the via-insulating layer VIA.

A pixel defining layer PDL may be formed on the via-insulating layer VIA. The pixel defining layer PDL may cover an edge of the pixel electrode PE and may define a pixel opening exposing an upper surface of the pixel electrode PE.

A light-emitting layer EML may be formed on the pixel electrode PE. The light-emitting layer EML may be formed in the pixel opening defined by the pixel defining layer PDL.

A common electrode CME may be formed on the pixel defining layer PDL and the light-emitting layer EML. The common electrode CME may be formed along profiles of the pixel defining layer PDL and the light-emitting layer EML. The encapsulation layer TFE may be formed on the common electrode CME.

FIG. 20 is a block diagram illustrating an electronic device according to an embodiment of the present disclosure.

Referring to FIG. 20, an electronic device 10 according to an embodiment may include a display module 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device.

The processor 12 may include at least one of a central processing unit (CPU), an application processor (AP), a graphic processing unit (GPU), a communication processor (CP), an image signal processor (ISP), and a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

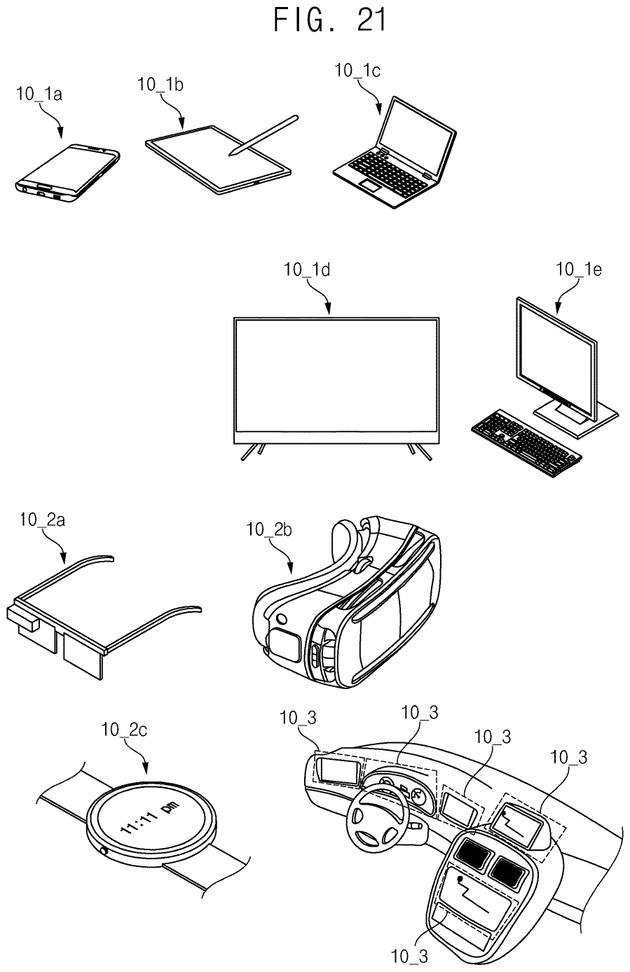

FIG. 21 is a schematic view of an electronic device according to various embodiments.

Referring to FIG. 21, various electronic devices to which a display device according to the embodiments is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be disposed on a instrument panel, a center fascia, and a dashboard of an automobile and a room mirror display, or the like.

The present disclosure may be applied to various display devices. For example, the present disclosure is applicable to various display devices such as display devices for vehicles, ships and aircraft, portable communication devices, display devices for exhibition or information transmission, medical display devices, and the like.

Although the display device of the present disclosure has been described with reference to the embodiments shown in the drawings, these are merely exemplary, and those skilled in the art will understand that various modifications and equivalent other embodiments are possible therefrom. Therefore, the disclosed subject matter should not be limited to any single embodiment described herein.

Moreover, features of various embodiments of the disclosure may be combined partially or totally. As will be clearly appreciated by those skilled in the art, technically various interactions and operations are possible. In addition, various embodiments can be practiced individually or in combination.

What is claimed is:

1. A display device, comprising:
a substrate;
an active pattern disposed on the substrate, the active pattern comprising a first conductor area, a second conductor area, and a channel area, the channel area being disposed between the first conductor area and the second conductor area;
a first gate insulating layer disposed on the active pattern, the first gate insulating layer overlapping the second conductor area and a portion of the channel area, and the first gate insulating layer being spaced apart from the first conductor area;
a second gate insulating layer disposed on the substrate, the second gate insulating layer covering the active pattern and the first gate insulating layer;
a gate electrode disposed on the second gate insulating layer, the gate electrode overlapping the channel area; and
a light-emitting element disposed on the gate electrode.

2. The display device of claim 1, wherein the first gate insulating layer comprises a first side surface and a second side surface, the first side surface and the second side surface being along a direction, the direction being parallel to a short side or a long side of the display device, the first side surface overlapping the channel area of the active pattern, the second side surface being a surface opposite to the first side surface, and the second side surface overlapping the second conductor area of the active pattern.

3. The display device of claim 2, wherein the first side surface of the first gate insulating layer overlaps a central portion of the channel area.

4. The display device of claim 2, wherein a side surface of the active pattern overlapping the second conductor area protrudes further in the direction away from a central portion of the active pattern compared to the second side surface of the first gate insulating layer.

5. The display device of claim 2, wherein a side surface of the active pattern overlapping the second conductor area and the second side surface of the first gate insulating layer are aligned parallel to each other when viewed in the thickness direction of the display device.

6. The display device of claim 2,
wherein the gate electrode overlaps the first side surface of the first gate insulating layer when viewed in the thickness direction, and
wherein the gate electrode is spaced apart from the second side surface of the first gate insulating layer when viewed in the thickness direction.

7. The display device of claim 1,
wherein the second gate insulating layer extends along a profile of an upper surface of the active pattern and a profile of an upper surface of the first gate insulating layer, and
wherein the gate electrode extends along a profile of an upper surface of the second gate insulating layer.

8. The display device of claim 2, wherein a sum of a thickness of the first gate insulating layer and a thickness of the second gate insulating layer disposed between the second conductor area and the gate electrode is greater than a thickness of the second gate insulating layer disposed between the first conductor area and the gate electrode.

9. The display device of claim 1,
wherein the second gate insulating layer has a flat upper surface such that a top surface of the second gate insulating layer has a same distance from the substrate in the thickness direction; and
wherein the gate electrode has a flat upper surface such that a top surface of the gate electrode has a same distance from the substrate in the thickness direction.

10. The display device of claim 1, further comprising:
a source electrode and a drain electrode disposed between the gate electrode and the light-emitting element,
wherein the source electrode is connected to the first conductor area through a first contact hole, the first contact hole penetrating the second gate insulating layer, and
wherein the drain electrode is connected to the second conductor area through a second contact hole, the second contact hole penetrating the first gate insulating layer and the second gate insulating layer.

11. A method of manufacturing a display device, the method comprising:
forming a preliminary semiconductor layer on a substrate;
forming a preliminary insulating layer on the preliminary semiconductor layer;
forming a photoresist layer on the preliminary insulating layer;
forming a photoresist pattern by exposing and developing the photoresist layer;
simultaneously etching the preliminary semiconductor layer and the preliminary insulating layer using the photoresist pattern as a mask to form an active pattern and a first gate insulating layer on the active pattern, the first gate insulating layer overlapping a portion of the active pattern;
forming a second gate insulating layer covering the active pattern and the first gate insulating layer on the substrate;
forming a gate electrode on the second gate insulating layer, the gate electrode overlapping the active pattern when viewed in a thickness direction of the display device; and
forming a light-emitting element on the gate electrode.

12. The method of claim 11,
wherein the photoresist pattern comprises a first portion and a second portion connected to the first portion, the first portion having a first thickness and the second portion having a second thickness, the first thickness being less than the second thickness, and
wherein the forming of the active pattern and the first gate insulating layer using the photoresist pattern as the mask comprises:
removing a portion of the preliminary semiconductor layer spaced apart from the photoresist pattern when viewed in the thickness direction of the display device; and
removing a first portion of the preliminary insulating layer spaced apart from the photoresist pattern when viewed in the thickness direction of the display device and removing a second portion of the preliminary insulating layer that overlaps the first portion of the photoresist pattern when viewed in the thickness direction of the display device.

13. The method of claim 11,
wherein the forming the photoresist pattern comprises exposing the photoresist layer using a photomask, and
wherein the photomask comprises a light-blocking pattern blocking light, a first light-transmitting portion having a first light transmittance, and a second light-transmitting portion having a second light transmittance, the second light transmittance being lower than the first light transmittance.

14. The method of claim 11, further comprising:
doping a portion of the active pattern after forming the gate electrode,
wherein the active pattern comprises a first conductor area, a second conductor area, and a channel area, the channel area being disposed between the first conductor area and the second conductor area.

15. The method of claim 14, wherein the first gate insulating layer comprises a first side surface and a second side surface in the first direction, the first side surface and the second side surface being along a direction, the direction being parallel to a short side or a long side of the display device, the first side surface overlapping the channel area of the active pattern, the second side surface being a surface opposite to the first side surface, and the second side surface overlapping the second conductor area of the active pattern.

16. The method of claim 15, wherein a side surface of the active pattern overlapping the second conductor area and the second side surface of the first gate insulating layer are aligned parallel to each other when viewed in the thickness direction of the display device.

17. The method of claim 15, further comprising:
cleaning the active pattern after forming the active pattern and forming the first gate insulating layer,
wherein the cleaning of the active pattern includes removing a portion of the second side surface of the first gate insulating layer, and
wherein the side surface of the active pattern overlapping the second conductor area protrudes further in the direction away from a central portion of the active pattern compared to the second side surface of the first gate insulating layer.

18. The method of claim 11,
wherein the second gate insulating layer is formed along a profile of an upper surface of the active pattern and a profile of an upper surface of the first gate insulating layer, and
wherein the gate electrode is formed along a profile of an upper surface of the second gate insulating layer.

19. The method of claim 11, further comprising:
polishing an upper surface of the second gate insulating layer after forming the second gate insulating layer,
wherein the second gate insulating layer has a flat upper surface such that a top surface of the second gate insulating layer has a same distance from the substrate in the thickness direction, and
wherein the gate electrode has a flat upper surface such that a top surface of the gate electrode has a same distance from the substrate in the thickness direction.

20. An electronic device, comprising:
a processor configured to transmit an image data signal and an input control signal; and
a display device configured to receive the image data signal and the input control signal from the processor,
wherein the display device comprises:
a substrate;
an active pattern disposed on the substrate, the active pattern comprising a first conductor area, a second conductor area, and a channel area, the channel area being disposed between the first conductor area and the second conductor area;
a first gate insulating layer disposed on the active pattern, the first gate insulating layer overlapping the second conductor area and a portion of the channel area, and the first gate insulating layer being spaced apart from the first conductor area;
a second gate insulating layer disposed on the substrate, the second the gate insulating layer covering the active pattern and the first gate insulating layer;
a gate electrode disposed on the second gate insulating layer, the gate electrode overlapping the channel area; and
a light-emitting element disposed on the gate electrode.
